(19) United States
(12) Patent Application Publication
(10) Pub. No.: US 2026/0018856 A1
(43) Pub. Date: Jan. 15, 2026

(54) PHOTONIC INTEGRATED CIRCUITS WITH REDUCED SENSITIVITY TO REFLECTIONS

(71) Applicant: Tin Komljenovic, Goleta, CA (US)

(72) Inventor: Tin Komljenovic, Goleta, CA (US)

(21) Appl. No.: 18/768,115

(22) Filed: Jul. 10, 2024

(51) Int. Cl. H01S 5/026; H01S 5/40

(52) U.S. Cl. CPC H01S 5/026; H01S 5/4006

(57) ABSTRACT

A device has a first element, comprising a semiconductor laser; a second element, comprising an attenuator providing at least 10 dB of optical attenuation; a third element, comprising a first optical amplifier; and a fourth element, comprising a first output facet. An optical output from the first element is coupled to the second element, an optical output from the second element is coupled to the third element, and an optical output from the third element is coupled to the fourth element. The first, second, third and fourth elements are realized as a single photonic integrated circuit, fabricated on a common substrate.

### FIELD OF THE INVENTION

The present invention relates to photonic integrated circuits. More specifically, certain embodiments of the invention relate to photonic integrated circuits that exhibit reduced sensitivity to reflections.

### BACKGROUND OF THE INVENTION

Single-mode semiconductor lasers offer an economical and compact laser source for many applications and are becoming increasingly popular in communications, sensing, metrology, atomic clocks, quantum systems and other applications. Despite their many advantages, these lasers have a notable vulnerability: sensitivity to optical feedback. Even minimal reflected light can lead to disruptive effects like mode hopping, frequency fluctuations, intensity variations, and heightened noise levels.

The impact of reflections can, in some cases, be mitigated by careful design of the system to minimize any reflection back into the laser cavity, but in some cases, this is not possible as the architectures of the system result in strong back-reflection.

One such case is the optical standard based on two-photon transition in rubidium. For optimal performance (as sketched in FIG. 1 and described below in more detail), the laser beam uses an in-line geometry for probing and measuring a two-photon transition, for which counter-propagating beams are necessary to avoid Doppler broadening of the transition. Counter propagation is ensured by using a retro-reflector, which necessarily results in very strong feedback affecting the laser. The strong back reflection directed into the laser can drastically impact the performance of the laser and compromise the performance of the optical standard.

Similar limitations can impact other systems, such as e.g. resonant optical gyroscopes, in which laser beams counter-propagate, and strong beams can be injected back into the laser, causing the instabilities mentioned above. Other systems may have similar limitations, especially if they use bidirectional light propagation, either due to the way light is routed, or due to imperfections (e.g. Rayleigh scattering) that can cause backscatter, or due to non-linear effects that can cause light generation in counter-propagating direction (e.g. Brillouin scattering).

The simplest way to mitigate back-reflections is to use an optical isolator that breaks symmetry by using the Faraday effect which involves rotating the plane of polarization of light. With a suitable arrangement of polarizers/analyzers and a Faraday rotator, high performance isolators can be realized. The Faraday rotator requires a magnetic field for the Faraday Effect to occur, and in most cases a permanent magnet is utilized to provide the magnetic field that rotates the plane of polarization plane. The use of an isolator can provide very high isolations, especially if dual-stage isolators are utilized, but this adds cost and system complexity, increases size, and can also impact the performance of some systems (such as magnetic sensors or clocks due to the generation of the magnetic field by the permanent magnet). Furthermore, the performance of isolators generally drops at shorter wavelengths due to material characteristics, resulting in significantly increased size, increased losses, and reduced isolation, in comparison to isolators operating at longer wavelengths (e.g. 1.3 μm and 1.55 μm, such as those typically used in communication systems). An example that illustrates this point is a typical miniature dual-stage 1.55 μm isolator, which can provide >40 dB isolation and have a transmission of >90% (or losses <0.5 dB), while a typical miniature single-stage 780 nm isolator may provide only 20 dB isolation and have a transmission of as low as 55% (or losses as high as 3 dB), and a corresponding dual-stage 780 nm isolator could have losses approaching 6 dB.

A way to address the performance problem is to replace semiconductor laser systems comprising discrete semiconductor lasers and isolators with photonic integrated circuits (PICs), comprising semiconductor lasers and supporting components, that are designed to provide reduced sensitivity to reflections. A PIC is a device that integrates multiple photonic functions and as such is analogous to an electronic integrated circuit. The major difference between the two is that a photonic integrated circuit provides functions for information signals imposed on optical carrier waves.

The present invention is directed towards PICs supporting advanced photonic integration to provide reduced sensitivity to reflections, and enabling, in many cases, operation without isolators even in the case of strong back reflections such as in optical clocks. In particular, embodiments described below are concerned with the detailed design of such PICs and individual components comprising such PICs.

### BRIEF DESCRIPTION OF THE DRAWINGS

FIG. 1 (prior art) shows an illustrative optical standard architecture with a laser and isolator.

FIG. 2 shows an illustrative optical standard architecture according to some embodiments of the present invention.

FIG. 3 shows a top-down view of a photonic integrated circuit with reduced sensitivity to reflections according to some embodiments of present invention, and a table and graph illustrating the benefits of using such embodiments of present invention.

FIG. 4 shows a top-down view of an advanced semiconductor laser with supporting components that in combination provide reduced sensitivity to back reflections.

FIG. 5 shows top-down views of components that may be used in some embodiments of the present invention.

FIG. 6 shows a cross-section view of one embodiment of the present invention.

### DETAILED DESCRIPTION

Described herein are embodiments of a platform for realization of photonic integrated circuits with reduced sensitivity to back reflection.

In the following detailed description, reference is made to the accompanying drawings which form a part hereof, wherein like numerals designate like parts throughout, and in which are shown by way of illustration embodiments in which the subject matter of the present disclosure may be practiced. It is to be understood that other embodiments may be utilized, and structural or logical changes may be made without departing from the scope of the present disclosure. Therefore, the following detailed description is not to be taken in a limiting sense, and the scope of embodiments is defined by the appended claims and their equivalents.

The description may use perspective-based descriptions such as top/bottom, in/out, over/under, and the like. Such descriptions are merely used to facilitate the discussion and are not intended to restrict the application of embodiments described herein to any particular orientation. The description may use the phrases “in an embodiment,” or “in embodiments,” which may each refer to one or more of the same or different embodiments. Furthermore, the terms “comprising,” “including,” “having,” and the like, as used with respect to embodiments of the present disclosure, are synonymous.

For the purposes of the present disclosure, the phrase “A and/or B” means (A), (B), or (A and B). For the purposes of the present disclosure, the phrase “A, B, and/or C” means (A), (B), (C), (A and B), (A and C), (B and C), or (A, B and C).

The term “coupled with,” along with its derivatives, may be used herein. “Coupled” may mean one or more of the following. “Coupled” may mean that two or more elements are in direct physical, electrical, or optical contact. However, “coupled” may also mean that two or more elements indirectly contact each other, but yet still cooperate or interact with each other, and may mean that one or more other elements are coupled or connected between the elements that are said to be coupled with each other. The term “directly coupled” means that two or more elements are in direct contact in at least part of their surfaces. The term “butt-coupled” is used herein in its normal sense of meaning an “end-on” or axial coupling, where there is minimal or zero axial offset between the elements in question. The axial offset may be, for example, slightly greater than zero in cases where a thin intervening layer of some sort is formed between the elements, such as e.g. thin coating layer typically used to provide high-reflectivity or anti-reflectivity functionality. It should be noted that the axes of two waveguide structures or elements need not be colinear for them to be accurately described as being butt-coupled. In other words, the interface between the elements need not be perpendicular to either axis. No adiabatic transformation occurs between butt-coupled structures.

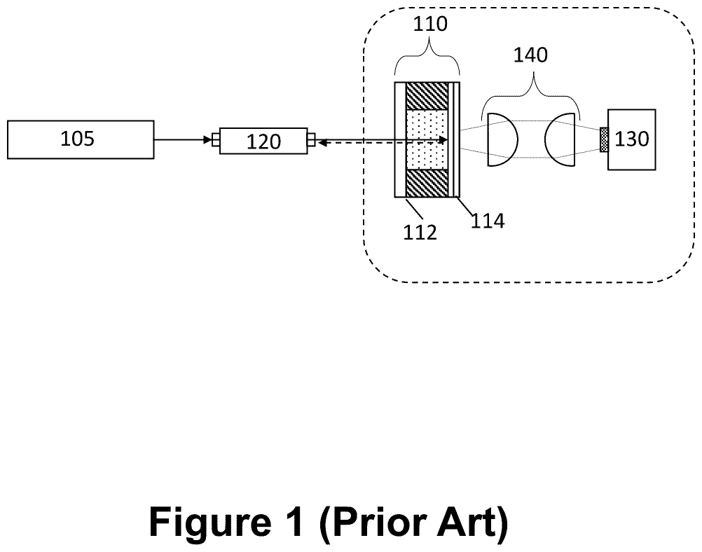

FIG. 1 (prior art) shows an illustrative architecture of a part of an optical standard, which consists of a semiconductor laser 105 operating at 778 nm, stabilized to a two-photon transition in Rubidium (Rb) using an Rb vapor cell 110. Additional elements such as e.g. a beamsplitter to tap part of the laser light for potential frequency down conversion, etc. are not shown. For additional details of some illustrative embodiments of the optical standard see e.g. Zachary L. Newman, Vincent Maurice, Connor Fredrick, Tara Fortier, Holly Leopardi, Leo Hollberg, Scott A. Diddams, John Kitching, and Matthew T. Hummon, “High-performance, compact optical standard,” Opt. Lett. 46, 4702-4705 (2021). The architecture employs an in-line geometry for probing and measuring the two-photon transition, in which the counterpropagating beams necessary for avoiding Doppler broadening of the transition are generated by retro-reflecting the laser off a high-reflectivity dielectric coating 114 on the back of a planar, microfabricated cell 110. The full lines show the forward propagating beam that leaves the laser, passes through the isolator 120 and is incident on the coated front window. The front window coating 112 serves to reduce the reflection at the interface before the beam reaches the Rb-vapor inside the cell. The back-side window coating 114 is designed such that the 778 nm probe signal is reflected, but its fluorescence at 420 nm is transmitted. The 778 nm signal that is reflected at the back-side window forms the counterpropagating beam that prevents Doppler broadening. This reflected beam is shown as the horizontal dashed line. After reflection and transmission through the Rb-vapor and front-side window, it is incident on isolator 120 which acts to prevent the beam from returning to the laser. In the absence of the isolator, most of the light in the reflected beam would travel back to the laser, causing the instabilities mentioned above. Meanwhile, the florescence signal at 420 nm is collimated by lenses 140 and detected by photomultiplier tube (PMT) 130 or by another type of high sensitivity photodetector (not shown). The Rb-cell 110 and other parts of the system can be placed in a magnetic shield to improve stability and other aspects of performance. In many cases, Rb-cell 110 is heated to temperatures of 60° C. to 120° C. The compact cell geometry reduces the sensitivity of the average power of the 778 nm probe beam to angular misalignment of the beam steering optics, as that sensitivity scales roughly with the square of the beam propagation length for the simple retro-reflection geometry shown.

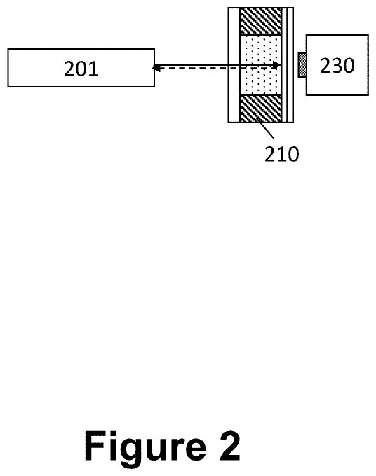

FIG. 2 shows one embodiment of the present invention in the form of an optical standard with a simplified architecture. The optical isolator of prior art is removed, and the stand-alone laser is replaced by a PIC that comprises a similar semiconductor laser but also includes other elements that cause the laser to have a reduced sensitivity to reflections. In the shown embodiment, the reflected beam is incident on PIC 201, but the architecture of the PIC is designed to prevent laser instabilities. In the absence of an isolator including a permanent magnet, there may be no need to use magnetic shields in some embodiments. Similarly, in some embodiments, such as the one shown, external lenses are not needed between Rb cell 210 and PMT 230, as the size of the complete system is significantly reduced, and sufficient florescence signal can reach PMT 230 without needing collimation or focusing optics.

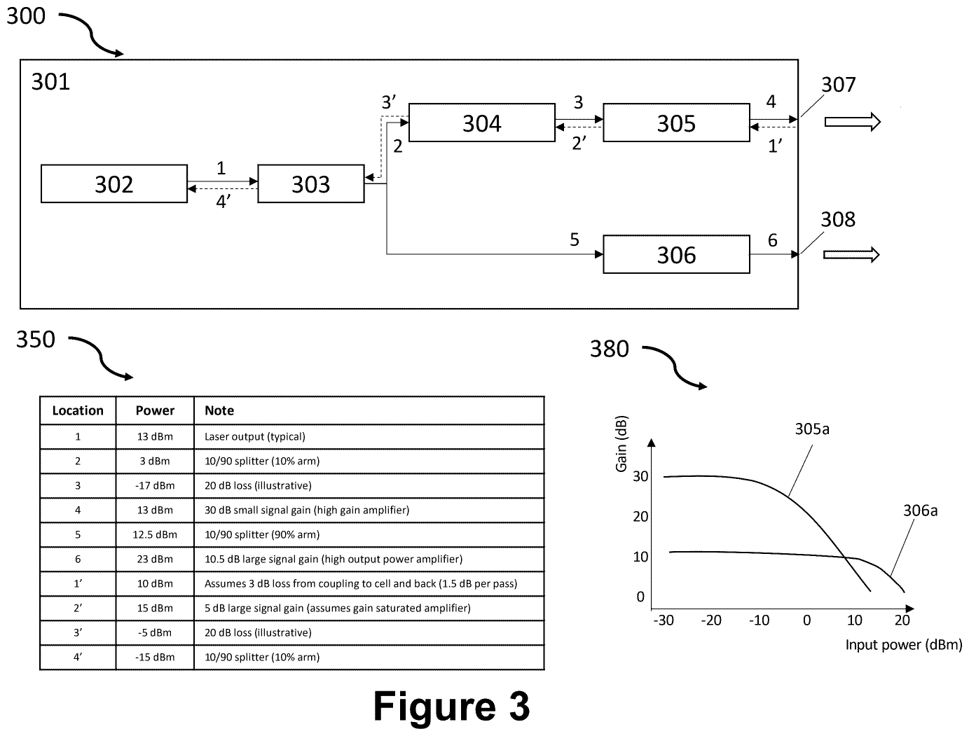

FIG. 3 shows a top-down view 300 of one embodiment of a PIC 301 according to the present invention, which has a reduced sensitivity to reflection, and could be used as PIC 201 in the optical standard embodiment of FIG. 2. Table 350 summarizes illustrative numbers for on-chip powers in an embodiment of the PIC 301 as will be described below, and plot 380 illustrates the effect of gain saturation in amplifiers 305 and 306, typical of semiconductor optical amplifiers of two different types, as will be described below.

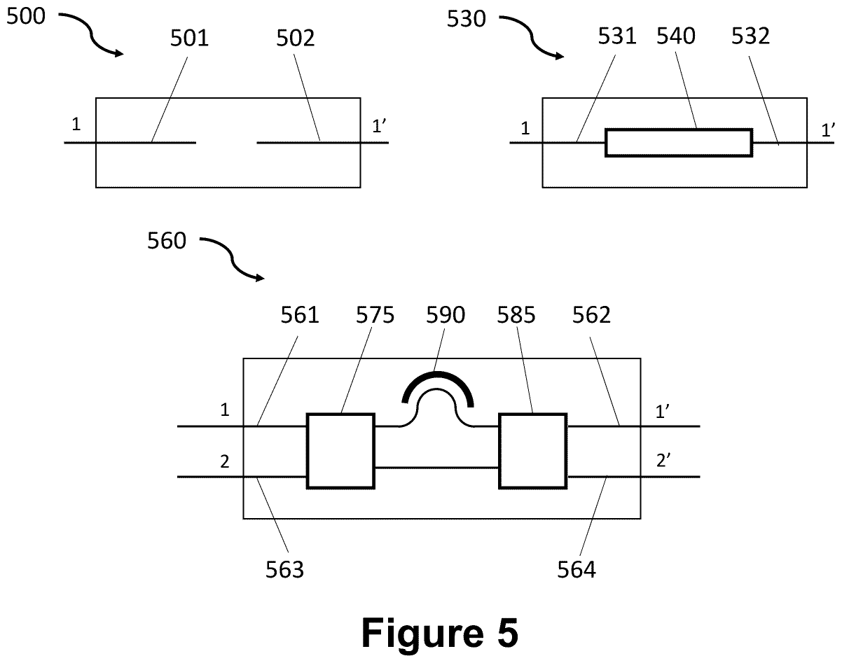

PIC 301 comprises a laser 302, splitter 303, attenuator 304 (that will be described in more detail with the help of FIG. 5), first and second amplifiers 305, 306, and first and second output facets 307 and 308 providing two corresponding output beams. Splitter 303 and second amplifier 306 are optional elements, meaning that in alternative embodiments, not shown, neither of them would be present, and no second output would be generated.

In this embodiment, arrows with full lines indicate forward propagating beams, while arrows with dashed lines indicate reflected beams, and numbers 1-6 correspond to specific locations along forward propagating beams, while numbers 1′-4′ correspond to specific, roughly corresponding, locations of backward propagating beams. These locations are used to describe an illustrative embodiment which may be characterized by the various power values shown in table 350, as discussed in detail below.

In the illustrated embodiment, the laser output is split into two parts, with a smaller part (10%) being directed to the attenuator, and the larger part (90%) being directed to the second amplifier. The reduced signal incident on the attenuator is further attenuated before being amplified by the first amplifier and then emitted from the PIC towards a vapor cell corresponding to cell 230 described with regard to FIG. 2.

In this particular exemplary embodiment, whose parameters are summarized in table 350, the laser emits+13 dBm of optical power at 778 nm (at location 1), and this incident power is split into two parts by a 10:90 splitter, with the 10% splitter arm connected to a 20 dB attenuator 304. The 10% splitting means that approximately +3 dBm of optical power (at location 2) reaches this attenuator, and passes through it, experiencing an attenuation of 20 dB, so that only-17 dBm (at location 3) reaches the first amplifier 305. This is a high gain amplifier, designed (as indicated by the illustrative upper gain curve 305a in view 380) to provide very high small signal gain of 30 dB, but to exhibit gain roll-off (gain compression) for higher power input signals. This means that output beam 307 will have a power of +13 dBm (at location 4), enabling vapor cell 330 to operate as desired.

Now, if we assume a typical loss in travelling from the output of the first amplifier to the vapor cell and back is 3 dB (amounting to 1.5 dB loss per pass) the reflected power (at location 1′) returning to the first amplifier will be 10 dBm. This power is so high that the beam will then experience a significantly lower amplifier gain as it passes through than the amplifier's small signal gain of 30 dB. In this illustrative embodiment, only a 5 dB gain will be provided for an input power of 10 dBm as indicated by the gain curve 305a in plot 380. This results in the reflected power being only+15 dBm as it leaves 305 (at location 2′) and travels on (from right to left in view 300) to reach attenuator 304. This attenuator has the same 20 dB attenuation for light passing through in forward and backward directions (due to reciprocity), so only-5 dBm (at location 3′) will leave amplifier 305 to return to splitter 303, which (due to reciprocity) transmits only 10% (10 dB loss) of that received power resulting in only-15 dBm of optical power being received back at the laser. The ratio of the power initially emitted by the laser (+13 dBm) to the reflected power received back by the laser (−15 dBm) is 28 dB, which is comparable to or even larger than the ratio that would be achieved if a typical miniature single-stage optical isolator around 778 nm had been used instead of the splitter/attenuator/amplifier combination of this embodiment. At the same time, higher output powers (compared to cases without a first amplifier) are incident on the vapor cell, as typically needed for 2-photon optical standards.

Returning to view 300, the other (shown lower in the figure) arm of the coupler transmits 90% of the laser output power, or around 12.5 dBm (at location 5), to the second amplifier 306. This second amplifier is optimized for high-output (saturation) power and high saturated input power (and typically has lower small signal gain) as indicated by the lower gain curve 306a in illustrative view 380). As shown in Table 350, the result is that the +12.5 dBm power will experience 10.5 dB of gain, providing second output beam with an output power of +23 dBm from the second output facet 308. In this embodiment, the PIC enables stable locking and Doppler-free spectroscopy of the vapor cell through output facet 307, while also providing a stabilized, high powered output from output facet 308.

In some embodiments (not shown), neither splitter 303 nor second amplifier 306 is present, so the laser output goes directly from laser 302 to attenuator 304 and to first amplifier 305 before being emitted from an output facet 307 of the PIC, typically towards a vapor cell (unshown). The attenuator serves to reduce the amount of reflected light reaching the laser, similarly to the situation described above, for a combination of attenuator and splitter. In some of these embodiments, the attenuator provides at least 10 dB of attenuation. The addition of the optional components, as described above, enable additional functionalities such as providing a high output power beam, that is stabilized with respect to the optical reference cell.

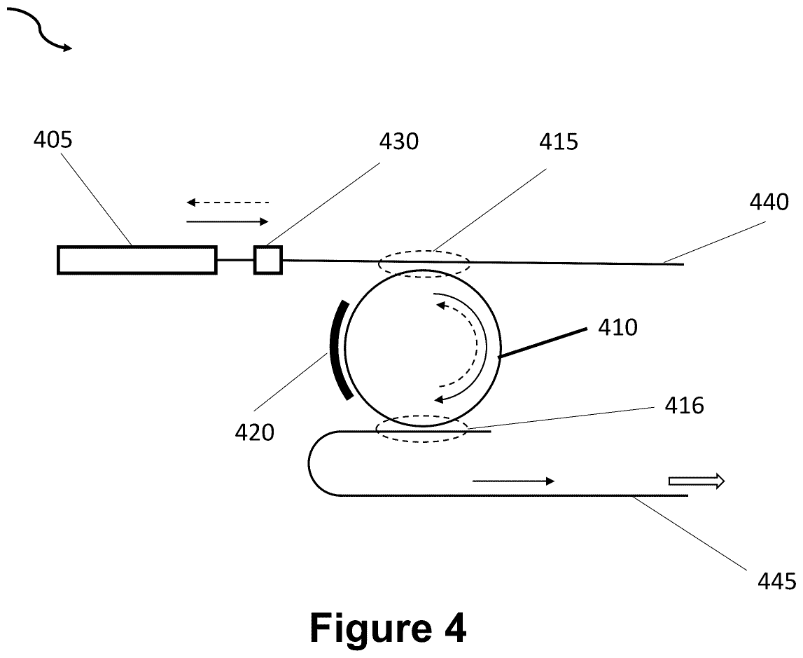

FIG. 4 shows a top-down view of one embodiment of a laser structure 400, that could correspond to laser 302 as described in relation to FIG. 3. Laser structure 400 includes a semiconductor laser 405, stabilized by injection-locking to a high-quality factor (high-Q) ring resonator 410. The definition of a high-Q resonator varies; in some cases, a resonator whose intrinsic quality factor is greater than 5 million is defined as high-Q. Resonator 410 is utilized in an add-drop configuration, having a primary laser output at one port 445, which may be called the drop port, while an output at another port 440, which may be called the through port can provide monitor functionality, or a secondary output. As described below, strong feedback from resonator 410 to laser 405 stabilizes the output of the laser structure by improving its resilience to the effects of reflections entering the structure at the primary laser output port 445. The add-drop functionality of resonator 410 is provided by two coupler/splitter structures 415 and 416 whose splitting ratios are optimization parameters depending on propagation loss, coupler/splitter loss and one or more other characteristics. The high-Q ring resonator can be operated in one of three regimes, under-coupled, critically-coupled or over-coupled, these three terms being familiar to those of skill in the art in describing such resonators.

As the regime of operation (determining whether it is under-coupled, critically coupled, or over-coupled) depends on coupler/splitter ratios as well as on internal resonator losses, including waveguide propagation loss, in some embodiments the coupler/splitter structures 415 and 416 are made tunable or adjustable. In this way, the combination of resonator, coupler/splitters/and control elements can be arranged to operate in the desired regime even if there are large fabrication process variations. Tunable coupler/splitters can be made in various ways, including e.g. pairing two couplers with phase control between, at least one of the arms connecting them, the phase control being, in some embodiments, thermally based.

The forward propagating (indicated by a full-line arrow) light exiting laser 405 passes through phase controller 430 and reaches coupler/splitter 415. One portion of this light passes through 415 to emerge from the laser structure 400 at monitor port 440, while another portion is redirected by 415 to enter ring 410. The arrangement shown in FIG. 4 operates according to principles well understood in the art, where coherent interference causes the light that enters resonator 410 from laser 405 via coupler/splitter 415 to be spectrally filtered and build up in power with each (clockwise as shown) cycle through the ring, while backscattering of that circulating light (due, for example, to waveguide sidewall roughness) creates counter-propagating (see dashed arrows) light, some of which is fed back into laser 405. This deliberate feedback effectively stabilizes laser 405 reducing RIN, and phase/frequency noise, and increasing its resilience to other feedback into the laser structure caused by any reflective elements (unshown) beyond output port 445. The level of backscattering in resonator 410 can be engineered by introducing intentional scattering that can be broadband or frequency selective. This is typically done by introducing defects or periodic structures that can be discrete, distributed, pseudo-randomized and/or randomized.

In this way the performance can be more deterministically engineered compared to using material and fabrication imperfection to provide backscattered signals, as the latter largely depends on the fabrication process, resulting in larger variation. In some other embodiments, backscattering at the splitter/coupler structures provides sufficient controlled back reflection.

The light output at port 440 is a coherent combination of light coupled out of coupler/splitter 415 directly from laser 405, without passage through ring 410, and light that circulates through ring 410 before being coupled out. The phase shift introduced by 415 added to the phase shift due to passage through ring 410 results in destructive interference, at some frequencies, providing a relatively low power output, that may in some embodiments provide useful monitoring functionality. The frequencies where this destructive interference happens can be adjusted via the resonator tuner 420 that can change the resonant wavelengths/frequencies of the resonator 410. In some embodiments, the resonator tuner 420 is a heater tuner element.

At coupler/splitter 416, there is no direct laser light interfering with power coupled out of the resonator, so, at resonance, larger signal levels are outcoupled and port 445 acts as a primary laser output power point. Phase tuner 430 and/or resonator tuner 420 are used to optimize injection-locking and/or feedback conditions. The output light from 445 is first stabilized by injection-locking the laser with signals returned from resonator 410, and then is additionally filtered by the add-drop frequency response of the resonator 410, significantly reducing amplitude and phase/frequency noise as well as improving resilience to reflections.

It should be noted that while FIG. 4 shows a ring resonator-based embodiment of the present invention, other embodiments may include other resonator geometries and coupling structure designs, operating to serve the same purpose of providing add-drop functionality, and stabilizing laser output. In yet other embodiments (not shown), there could be additional high-Q ring resonator or resonators coupled to resonator 410 which can enable engineering of dispersion, or provide more advanced filtering capabilities.

FIG. 5 shows three embodiments of an attenuator element that could correspond to attenuator 304 as described in relation to FIG. 3. The three embodiments are shown in cross-sectional top-down views 500, 530 and 560.

View 500 shows a fixed attenuator that uses a discontinuity between two waveguides to introduce a fixed loss experienced by light that enters waveguide 501 at port 1, and leaves output waveguide 502 at port 1′ (or vice versa for light traveling from right to left in the orientation shown). The loss can be set to the desired value simply according to the length of a gap between axially aligned waveguides, as shown in view 500, but it may also be set according to the magnitude of a vertical and/or angular misalignment between two waveguides (not shown). Numerical simulations can model the loss between ports 1 and 1′ for any of the above mentioned geometries, and values of loss can be set to be anywhere between 0 dB and a very large number, exceeding 60 dB, for example.

View 530 shows a controllable attenuator that uses a semiconductor optical amplifier (SOA) 540 in between the input waveguide 531 having port 1, and output waveguide 532 having port 1′. Optical amplifiers can provide gain, as described above is the discussion of FIG. 3 and more specifically of view 380, but they can also provide attenuation if they are reverse biased. Extinction ratios as high as 60 dB or more have been demonstrated when first operating SOAs in forward bias (providing 10+dB of gain), and then operating SOA in reverse bias in which SOAs can achieve >20 dB/mm attenuation, where attenuation is typically a function of confinement in the active region, amplifier length, and reverse bias voltage. A benefit of using an attenuator as shown in view 530 compared to a waveguide discontinuity as shown in view 500 is the ability to adjust the attenuation, although this is at the expense of requiring the application of electrical control signals.

View 560 shows a controllable attenuator that uses a tunable Mach-Zehner interferometer or tunable coupler rather than an SOA. In the most general case, a structure of this sort has four ports, two inputs (1 and 2), and two outputs (1′ and 2′), but in some embodiments, not all four ports are present. A signal incident to either of the input ports 1 or 2, and then passing through waveguides 561 or 563 respectively is split into two parts via a first splitter 575, preferably a 50:50 splitter so that the two parts are equal in amplitude or power. The two parts are then propagated through two connecting waveguides to reach a second splitter 585, which splits them further, into four parts. Interference then occurs between the paired parts leaving splitter 585 along waveguides 562 and 564 to output ports 1′ and 2′ respectively. The fraction of the entering optical power delivered to either of the two output ports can be selected by adjusting the phase relationship between the corresponding interfering parts, and consequently attenuation can be provided, of e.g. the signal passing from port 1 to port 1′. The phase relationship can be controlled via a tuner element 590. In some embodiments, the tuner is a heater that can change the effective refractive index of at least one of the waveguides connecting splitters 575 and 585. The extinction ratio of the controllable attenuator depends on the splitting ratio of splitters. In the ideal case, when both splitters are perfect 50:50 splitters and there is no additional loss, the extinction ratio is infinite, but in practice lower values are achieved, due to slight power differences between the arms. By adjusting the tuner element, the extinction ratio can typically be tuned through a range from close to 0 dB (depending on losses and imbalance), to a maximum that depends on losses and imbalance. In some practical cases the maximum value is 20 dB to 40 dB.

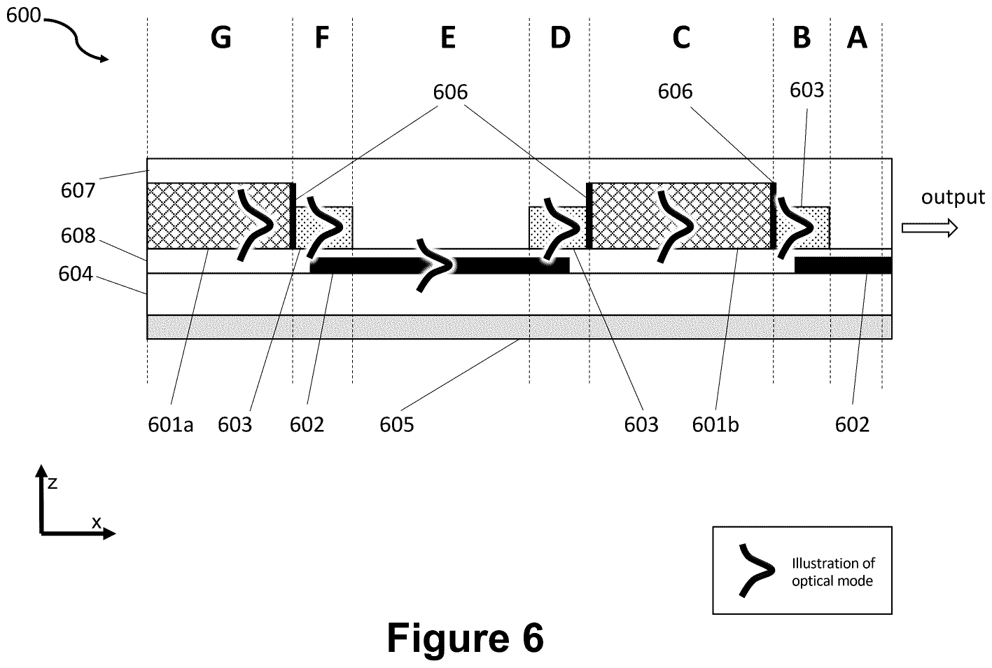

FIG. 6 shows a cross-section view 600 of one embodiment of a photonic integrated circuit platform in which some embodiments of the present invention may be realized. The shown embodiment includes substrate 605, which can be any suitable substrate for semiconductor and dielectric processing, such as Si, InP, GaAs, quartz, sapphire, glass, GaN, silicon-on-insulator or other materials known in the art. Layer 604, on top of substrate 605, provides optical cladding for layer 602 (described below), if necessary to form an optical waveguide. In some embodiments, layer 604 comprises SiO₂ and/or SiNOₓ. In some embodiments, layer 604 is omitted and substrate 605 itself serves as a cladding, e.g. in the case layer 605 is a lower refractive index material such as quartz, sapphire, glass, etc.

Layer 602 has low propagation loss and provides additional passive waveguide functionality such as wide-band transparency, high intensity handling, phase shifting by temperature, combining, splitting, filtering, non-linear generation and/or others as is known in the art. Layer 602, due to the low propagation loss, would be the layer in which resonators would be made (as described in relation to FIG. 4). The refractive index of layer 602 is higher than the refractive index of layer 604 if present, or, if layer 604 is not present, the refractive index of layer 602 is higher than the refractive index of substrate 605. In one embodiment, the material of layer 602 may include, but is not limited to, one or more of SiN, SiNOₓ, TiO₂, Ta₂O₅, (doped) SiO₂, LiNbO₃ and AlN.

Layer 608, whose refractive index is lower than the refractive index of layer 602, serves to planarize the patterned surface of layer 602. The planarization may be controlled to leave a layer of desired, typically very low, thickness of layer 608 on top of the layer 602 (as shown in view 600), or to remove all material above the level of the top surface of the layer 602 (not shown). In the cases where layer 608 is left on top of layer 602, the target thicknesses on top of layer 602 are in the range of a few nm to several hundreds of nm, with actual thickness, due to planarization process non-uniformities, being between zero and several hundreds of nanometers larger than the target thickness. In yet another embodiment (not shown), there is no planarization layer 608 filling in etched regions of layer 602. In this embodiment there would be depressions or pockets where layer 602 was etched. In the shown embodiment, layer 602 is not present below layer 601a or 601b (see discussion below). In other embodiments (not shown) layer 602 (patterned or un-patterned) is present below at least one of layers 601a/601b.

In the shown embodiment, layers 601a and 601b are attached directly onto the planarized top surface comprising layers 602 and/or 608. In other unshown embodiments, there could be additional thin layers between layer 602/608 and 601a/601b to facilitate higher yield attachment. The attachment can utilize direct molecular bonding (with or without supporting thin layers) or can use additional materials to facilitate bonding such as e.g., metal layers or polymer films as is known in the art. Layers 601a/601b make up what is commonly called an active device, and may be multilayered and/or patterned to provide optical and electrical confinement as is known in the art of active semiconductor devices such as optical sources, modulators, amplifiers and detectors. Layers 601a/601b, in some embodiments, comprise at least one of GaAs, InP and/or GaN materials and their ternary and quaternary materials.

In some embodiments, layers 601a and 601b are identical and can be bonded in a single step; one such example would be layer 601a providing laser functionality and layer 601b providing amplifier/attenuator functionality, in which both can comprise a gain optimized structure comprising quantum wells or quantum dots. In other embodiments, layers 601a and 601b are different, and the process can include two bonding steps. In such embodiments, they can have significantly different structures, e.g. layer 601a can provide laser functionality, while layer 601b provides high small signal gain, or high output power amplifier capability. This could, for example, be enabled by controlling the confinement factor in the active (quantum well/quantum dot) region as well as internal loss, optical mode size, etc. as is known in the art of high output power semiconductor amplifiers.

Efficient coupling between waveguides realized in layers 601a/601b and waveguides realized in layer 602 is facilitated by layer 603, and, in cases where layer 606 is present, by layer 606. Optional layer 606 is a coating that primarily serves as either an anti-reflective or a highly reflective coating at the interface between layer 601 and layer 603. Layer 603 is typically deposited on top of the planarized surface comprising layers 602 and/or 608, depending on the nature of planarization as described above in relation to layer 608. Layer 603 has a lower refractive index than layer 602, and higher refractive index than layers providing cladding functionality (604, 608 and/or 607 which is described below).

In this illustrative embodiment, the mode progression from left to right in FIG. 6 goes roughly as follows. Layer 603 serves as an intermediate waveguide core that in some embodiments accepts the profile of an optical mode supported by the waveguide for which layer 601a in the region indicated by “G” provides the core, captures it efficiently as the mode profile shown in region “F”, and gradually transfers it to the mode profile shown in region marked “E” for which layer 602 provides the core. This mode can then be gradually transferred back to the mode for which layer 603 provides the core in region “D” before transferring it to an optical mode supported by the waveguide for which layer 601b in region “C” provides the core. This mode is transferred to another mode in region “B” supported by the waveguide in which layer 603 provides the core before gradually being transferred to a mode having the mode profile shown in region marked with “A” for which layer 602 provides the core. Finally, this last mode is coupled via an output facet to free-space, fiber and/or other apparatus (e.g., vapor cell, not shown).

The transitions from regions “G” to “F”, “D” to “C” and “C” to “B” utilize butt-coupling, in which coupling efficiency is maximized by optimizing the mode shapes at the butt-coupled interface for maximum overlap, and optionally utilize anti-reflectivity coatings 606. In these butt-coupling cases, the waveguides do not overlap in a vertical dimension (along the z-axis in view 600). The transitions from regions “F” to “E”, “E” to “D”, and “B” to “A” utilize evanescent coupling in which waveguides do overlap in a vertical dimension (along the z-axis in view 600), and their cores (defined in 602 and 603) have dimensions optimized to support evanescent coupling, using tapers in at least one of the waveguides of each pair. Tapers are not visible in view 600, but would be visible in a cross-sectional view, in the x-y plane.

The refractive index and dimensions of layer 603 can be engineered to facilitate efficient butt-coupling of its supported mode profile to corresponding profiles in active regions 601a/601b, as well as to efficiently transform modes by taking advantage of tapered structures made in layer 602 and/or 603. The requirements on taper dimensions for evanescent coupling are reduced as the refractive index difference of layers 602 and 603 is typically smaller than the refractive index difference between layer 601a/601b and 602. As layer 603 is generally thicker in the z-direction than 602, its refractive index is smaller to simplify phase matching without requiring prohibitively narrow taper tips.

Layer 607 is the upper cladding layer and can comprise polymer, SiO₂, SIN, SiNOₓ etc. In some embodiments (not shown), layer 607 cladding functionality can be provided with multiple depositions and/or multiple materials to e.g. manage stress or provide additional functionality (e.g. surface passivation for layers 601a/601b).

Active devices (601a/601b) also have electrical contacts to provide electrical signals to control the device, e.g. inject carriers in the case of optical semiconductor amplifier (not shown). Common alignment mark(s) are used to align process steps in forming the complete structure including the patterning of layers 601a/601b after bonding. In some embodiments, alignment marks are defined in layer 602, not visible in view 600 but would be in cross-section x-y if shown.

In some embodiments, the resonators, splitters and attenuators discussed in relation to views 400, 500 and 560 are realized in layer 602, and lasers and amplifiers are realized in layers 601a/601b.

In other embodiments, splitters and resonators are realized in layer 602, while attenuators of the type discussed in relation to view 530, and lasers and amplifiers are realized in layer 601a/601b.

It is obvious to someone skilled in the art the multiple combinations of the above approaches that combine on-chip loss elements and amplifiers can be utilized to control the impact of reflection to semiconductor lasers integrated on the same PIC.

It is to be understood that these illustrative embodiments teach just several examples of photonic integrated circuits having on-chip lasers with reduced sensitivity to reflections utilizing the present invention, and many similar arrangements can be further envisioned. Furthermore, such lasers and active components can be combined with multiple other components to provide additional functionality or better performance such as various filtering elements, amplifiers, monitor photodiodes, modulators, single-frequency lasers, widely tunable lasers, broadband optical sources and/or other photonic components. Embodiments of the present invention offer many benefits. The integration platform enables scalable manufacturing of PICs made from multiple materials providing higher-performance and/or ability to operate in broadband wavelength range.

This present invention utilizes a process flow consisting of typically wafer-bonding of a piece of compound semiconductor material on a carrier wafer with dielectric waveguides and subsequent semiconductor fabrication processes as is known in the art. It enables an accurate definition of optical alignment between components via typically photo lithography step, removing the need for precise physical alignment. Said photo lithography-based alignment allows for scalable manufacturing using wafer scale techniques.

Embodiments of the optical devices described herein may be incorporated into various other devices and systems including, but not limited to, various computing and/or consumer electronic devices/appliances, communication systems, medical devices, timing devices, quantum devices, sensors and sensing systems.

It is to be understood that the disclosure teaches just few examples of the illustrative embodiment and that many variations of the invention can easily be devised by those 10 skilled in the art after reading this disclosure and that the scope of the present invention is to be determined by the following claims.

1. A device comprising:
a first element, comprising a semiconductor laser;
a second element, comprising an attenuator providing at least 10 dB of optical attenuation;
a third element, comprising a first optical amplifier; and
a fourth element, comprising a first output facet;
wherein an optical output from the first element is coupled to the second element, an optical output from the second element is coupled to the third element, and an optical output from the third element is coupled to the fourth element; and
wherein the first, second, third and fourth elements are realized as a single photonic integrated circuit, fabricated on a common substrate.

2. The device of claim 1,
wherein the attenuator is realized as a waveguide discontinuity.

3. The device of claim 1,
wherein the attenuator is realized as a semiconductor optical amplifier operated in reverse bias.

4. The device of claim 1,
wherein the attenuator is realized as a tunable coupler.

5. The device of claim 1,
wherein the first element further comprises a resonator to which the semiconductor laser is injection locked, the resonator having an intrinsic quality factor greater than 5 million.

6. The device of claim 5,
wherein the resonator is in an add-drop configuration, having a through port and a drop port, a primary optical output exiting the device through the drop port.

7. The device of claim 1,
additionally comprising a fifth element comprising a splitter accepting an input from the first element, and a sixth element comprising a second output facet;
wherein an output from the first element is split into first and second portions by the splitter, the second portion being larger than the first portion;
wherein the first portion is transmitted through the second, third and fourth elements in turn, providing a corresponding first output portion exiting the first output facet; and
wherein the second portion is transmitted through the sixth element, providing a second output portion exiting the second output facet.

8. The device of claim 7,
additionally comprising a seventh element comprising a second optical amplifier;
wherein the second portion of the output from the fifth element is coupled to the seventh element before being coupled to the sixth element.

9. The device of claim 8,
wherein the first optical amplifier of the third element has small signal gain greater than 20 dB, and second optical amplifier of the seventh element has higher output saturation power than the first optical amplifier.

10. The device of claim 1,
wherein an output from the first optical facet is coupled to a vapor cell configured in a retro-reflector configuration.

11. The device of claim 6,
wherein an output from the first optical facet is coupled to a vapor cell configured in a retro-reflecting arrangement.

12. The device of claim 7,
wherein an output from the first optical facet is coupled to a vapor cell configured in a retro-reflecting arrangement.
